(19) United States
(12) Patent Application Publication
(10) Pub. No.: US 2004/0056333 A1
(43) Pub. Date: Mar. 25, 2004

(54) Electromagnetic traps in integrated circuit for minimizing cross-talk

(76) Inventors: Hung Chang Lin, Silver Spring, MD (US); Sesha Rajamani Shankar, Germantown, MD (US); Jonathan Glen Pfeifer, North Potomac, MD (US)

Correspondence Address: Hung Chang Lin, 8 Schindler court, Silver Spring, MD, 20903, US

(21) Appl. No.: 10/252,883

(22) Filed: Sep. 24, 2002

(51) Int. Cl. H01L 23/552; H01L 29/94

(52) U.S. Cl. 257/659; 257/660; 257/409

(57) ABSTRACT

An integrated circuit is divided into a number of sub-circuits by isolation walls in the substrate. A conducting shield overlays every sub-circuit to form a grounded cage with the underlying substrate for trapping electromagnetic radiation generated inside the sub-circuit, and to prevent cross-talk between the sub-circuits.

### BACKGROUND OF THE INVENTION

(1) Field of the Invention

This invention relates to integrated circuit (IC) structures, particularly to IC structures to reduce cross-talk.

(2) Brief Description of Related Art

The tendency in IC technology is to reduce the minimum resolution in an IC structure so as to increase the packing density. As the packing density increases, different sections of an IC are placed closer together. The close proximity of the sections may cause cross talks among each other, because the interconnections in one section may radiate electromagnetic waves which may be picked up by a neighboring section. The cross-talk can cause interference and/or oscillations. Such cross-talks are particularly serious in analog or mixed-signal ICs. One technique widely used in the IC structures is to build conducting walls around different sub-circuits SC1, SC2 as shown in FIG. 1. A wall 12 is built to surround each sub-circuit and is grounded. Each circuit section may include circuit elements such as transistors, resistors, capacitors, etc. and interconnections (not shown). The wall serves as a shield to prevent lateral electromagnetic (EM) radiation of the circuit elements, particularly the interconnections due to RF current flow. However, the circuit interconnections can serve as antennas to propagate over the top of the IC chip and be picked up by a neighboring sub-circuit.

Another technique widely used in IC design is to use differential pairs (amplifiers) and place the paired input and output wires of differential pairs close to each other, so that the currents in the paired wires run in opposite directions to cancel the radiation. Such a technique may impose restriction on circuit layout and has not proven to be very effective.

### SUMMARY OF THE INVENTION

An object of this invention is to minimize cross-talk due to EM interference. Another object of this invention is to prevent the radiation of EM wave over the top surface of any IC section. Still another object of this invention is to increase the flexibility in laying out integrated circuits.

These objects are achieved by covering each sub-circuit with an electromagnetic shield. Any EM waves generated within that particular sub-circuit are trapped and prevented from radiating outside the trap. The walls of the shield are grounded. Thus, any neighboring sub-circuit is prevented from picking up any interference.

### BRIEF DESCRIPTION OF THE SEVERAL VIEWS OF THE INVENTION

FIG. 1 shows a prior art IC structure to reduce cross-talks

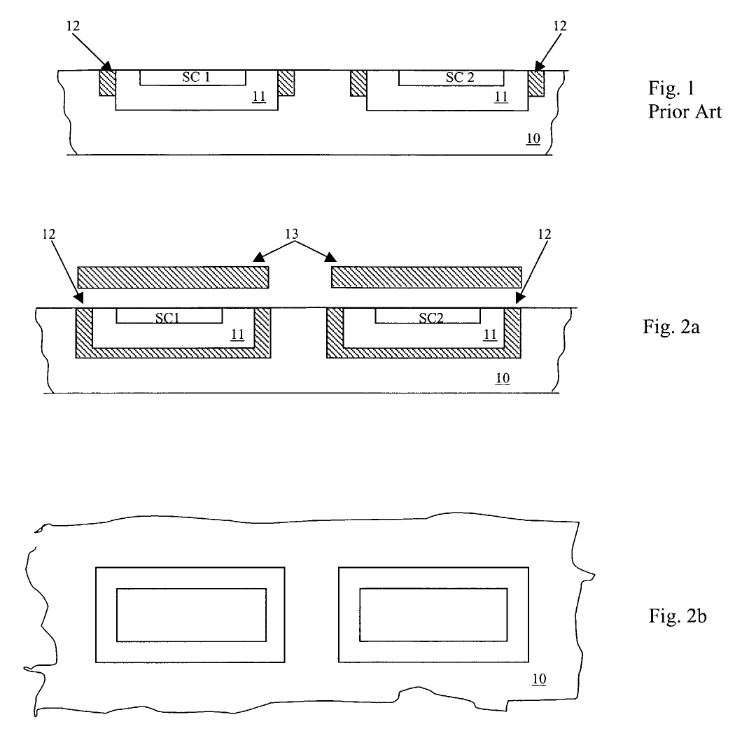

FIG. 2a shows the basic cross-section view of the shielded cage of the present invention; FIG. 2b shows the top view of the shielded cage.

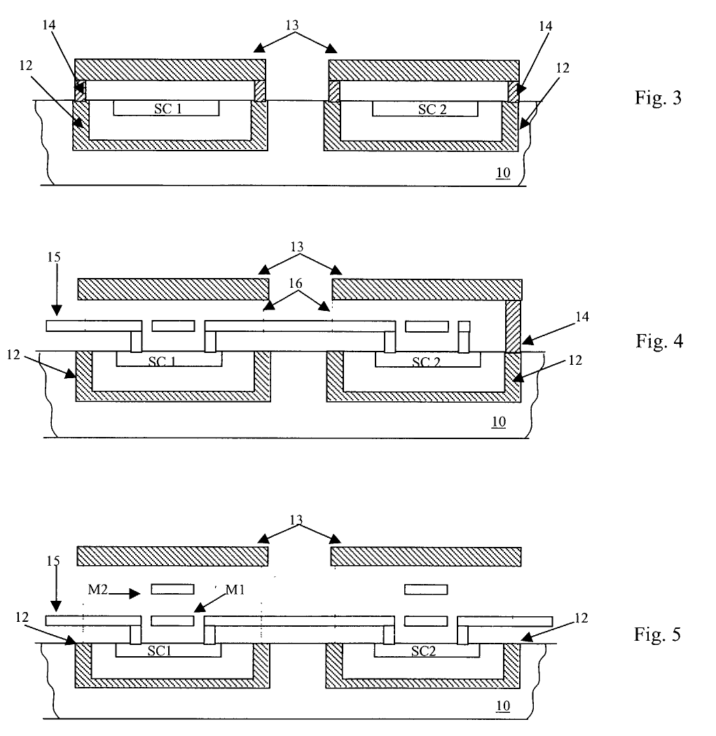

FIG. 3 shows the washer of the shielded cage.

FIG. 4 shows the feed through for the shielded cage.

FIG. 5 shows the shielded cage for sub-circuit with multi-layer interconnection.

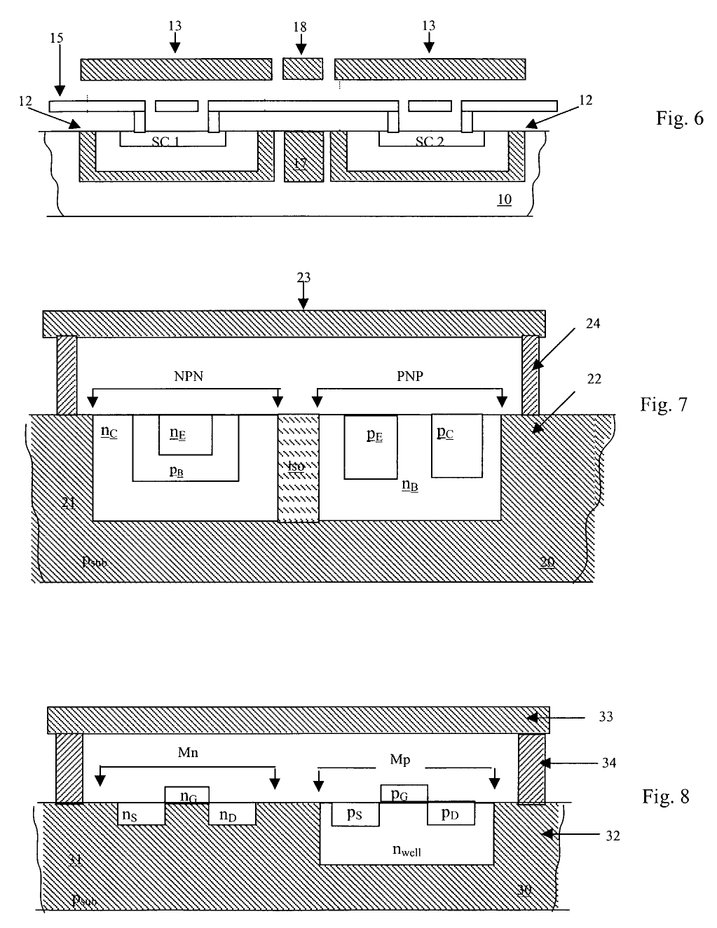

FIG. 6 shows a shielded interconnection.

FIG. 7 shows the construction of a shielded cage for a BJT integrated sub-circuit.

FIG. 8 shows the construction of a shielded cage for a CMOS integrated sub-circuit.

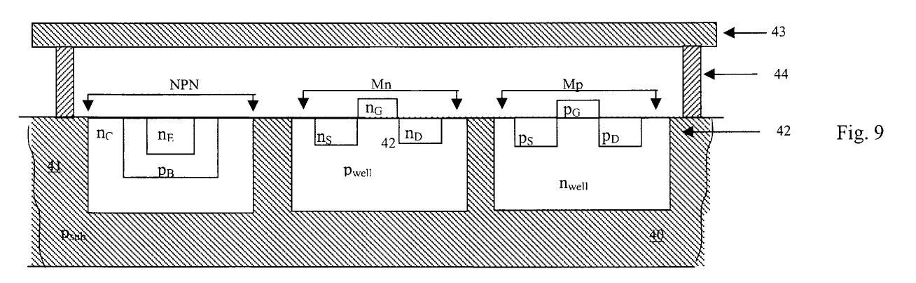

FIG. 9 shows the construction of shielded cage for a BiCMOS integrated sub-circuit.

### DETAILED DESCRIPTION OF THE INVENTION

FIG. 2(a) and FIG. 2(b) show the basic structure of the present invention. FIG. 2(a) shows the cross-sectional view of the structure. As in the prior art, conducting walls 12 are imbedded in the substrate to surround the substrates SC1 and SC2 separately. Separate conductive shields 13 cover over the respective sub-circuits SC1, SC2, as shown in the top view FIG. 2(b). Thus, the sub-circuits are caged inside the surrounding walls 12 and the overhanging shields 13. The cages are grounded and trap any EM waves generated in the sub-circuits, preventing the radiation of the EM waves outside the cage.

FIG. 3 shows a second embodiment of the invention. A washer 14 is added to each cage between the imbedded wall 12 and the shield 13. The washers serve as spacers to allow enough space for the interconnections and interleaving insulators.

FIG. 4 shows a third embodiment of the present invention. Through-holes 16 are inserted in the washers 14 for leads connected outside the sub-circuits to feed through.

FIG. 5 shows the cross-section view of a structure with multi-layer interconnections, M1, M2. More layers of interconnections and insulators can alternately be stacked over the substrate 10.

FIG. 6 shows a fourth embodiment of the present invention. In addition to caging of the sub-circuits, the interconnection between two sub-circuits can also be shielded. As shown, the interconnection between sub-circuit SC1 and SC2 is shielded by the sleeve comprising an imbedded wall 17 and cover 18. Similar to the shields for the sub-circuits, the shielding wall 17 and cover 18 are also grounded.

The processing of the shielding cages can be compatible with the conventional fabrication method for integrated circuits. The methods depend on whether the IC is based on a BJT, CMOS, BiCMOS or any other structure. FIG. 7 shows a basic BJT IC structure. FIG. 8 shows a basic CMOS IC structure. FIG. 9 shows a basic BiCMOS structure.

FIG. 7 shows a cross-sectional view of the implementation of the concept for a typical bipolar (BJT) integrated circuit. The sub-circuit 21 on the p-type substrate 20 and an n-type well may include a vertical NPN BJT and a lateral PNP BJT. Other components such as diodes, resistors, capacitors etc. may be placed beside the transistors. The sub-circuit may include an isolation ISO to separate the NPN transistor and the lateral PNP transistor such as a p-type sinker diffusion, and be placed in the p-type substrate p_{sub}. Such an isolation and the p-type substrate p_{sub} together form the bottom wall 22 of the EM cage. As to the sleeve-like washers 24 over the bottom wall 22, the washer can be formed by stacking multiple layers of metallization. Only an additional metal shield 23 need be deposited over the bottom wall 22. The shield should be the topmost metal layer of the interconnection system. If the topmost metal or poly-silicon layer is not used for interconnection, the shield can be formed without any extra metallization. Through-holes in washer 24 are provided as needed for interconnections between sub-circuits. The substrate 20 and the shield 23 are all grounded together.

FIG. 8 shows a cross-section of the implementation for a CMOS integrated circuit.

The sub-circuit 31 on substrate 30 may include an NMOS FET Mn in the p-substrate and PMOS FET Mp in an n-well n_{well} as shown. These wells are normally grounded or ac grounded, thus forming the bottom wall of the EM cage. Since the p-substrate and the n-well are self isolating, there is no need to add additonal side wall for the EM cage. The washer 34 over the bottom wall can be fabricated by stacking multiple metal layers. As in the BJT structure, at most only one extra metal shield 33 need be deposited over the bottom wall 32. The shield 33 should be the top metal layer and is connected electrically by the sleeve-like washer 34 to ground. Through-holes in the washer 34 can be provided as needed for interconnections as described in FIG. 4.

FIG. 9 shows a cross-sectional view of the implementation for a BICMOS integrated circuit. The subcircuit 41 on substrate 40 may comprise CMOS elements such as NMOS and PMOS, and bipolar elements such as NPN BJT transistors as well as other elements such as diodes, resistors, capacitors etc. fabricated on a p-type substrate p_{sub}. The NPN bipolar transistor has n-type emitter n_{E}, p-type base p_{B} and n-type collector n_{C}. On the same p type substrate can be diffused with the source n_{S} and drain n_{D} of the NMOS FET. An n-type well is formed in the p-type substrate and diffused with p-type source p_{S} and drain p_{D} for the construction of an NMOS FET. The p-type substrate now can serve as the lower wall of the EM cage. The washer 44 can be fabricated by stacking multiple layers of metal. The top is shielded by the shield 43 and is electrically connected to the surrounding wall 42 by sleeve-like conducting washer 44 for complete enclosure and is grounded. Through-holes in the washer 44 may be provided wherever needed for interconnections between different sub-circuits.

From the foregoing description in FIGS. 7, 8 and 9, it can be seen that the fabrication of the EM cage is compatible with the fabrication of basic BJT, CMOS and BiCMOS IC structures. In most cases, at most one additional metal layer is needed. No additional area is needed to incorporate the shield, since it overlays over the bottom well While p-type substrates are used in these structures, dual structures using complementary conductivity type semiconductors can obviously be used.

While the preferred basic embodiment of the invention have been described, it will be apparent to those skilled in the art that various modifications can be made in the embodiments without departing from the spirit of the present invention. All such modifications are all within the scope of this invention.

1. A semiconductor integrated circuit (IC) structure with provision for reducing electromagnetic cross-talk, comprising:
a semiconductor substrate;
a plurality of sub-circuits with circuit elements and interconnections fabricated on said sub-circuits;
isolation walls between adjacent sub-circuits; and
a conducting shield overlaying each one of said sub-circuit to form a cage with said isolation walls enclosing each one of said sub-circuit to trap any electromagnetic radiation generated in each one of said sub-circuits.

2. The semiconductor IC structure as described in claim 1, wherein said cage is grounded.

3. The semiconductor IC structure as described in claim 1, further comprising a conducting washer between each one of said isolation walls and said conducting shield to make room between the sub-circuit and the conducting shield.

4. The semiconductor IC structure as described in claim 3, further comprising feed-through doors for interconnections inside each one of said sub-circuits to feed outside said sub-circuits.

5. The semiconductor IC structure as described in claim 4, further comprising shielding sleeve covering said interconnections outside said sub-circuit.

6. The semiconductor IC structure as described in claim 3, wherein bipolar transistors (BJT) are used in said sub-circuits.

7. The semiconductor IC as described in claim 6, wherein:
said substrate is of p-type,
an n-type layer is deposited over said p-type substrate,
isolation walls are formed in the n-type layer to form a plurality of islands for the fabrication of said sub-circuits and to connect with said p-type substrate to form the bottom section of said cage.

8. The semiconductor IC as described in claim 3, wherein CMOS FETs are used in said subs circuits.

9. The semiconductor IC as described in claim 8, wherein:
a p-type substrate is used,
n-type source and drain of a NMOS FET are formed in the p-type substrate,
an n-type well is formed in said substrate,
p-type source and drain of a PMOS FET is formed in said n-type well, and
the area in the p-type substrate overlaid by said top shield forms the walls of said cage.

10. The semiconductor IC as described in claim 3, wherein both BJT and CMOS FETs are used in said sub-circuits.

11. The semiconductor IC as described in claim 10, wherein:
a p-type substrate is used,
n-type source and drain of a NMOS FET are formed in the p-type substrate,
a first n-type well and second n-type well are formed in said p-type substrate,
a NPN BJT is formed in said first n-type well,
p-type source and drain of a PMOS FET are formed in said second n-type well, and
the area in the p-type substrate overlaid by said top shield forms the walls of said cage.
